(19) United States
(12) Patent Application Publication
(10) Pub. No.: US 2021/0134879 A1
(43) Pub. Date: May 6, 2021

(54) SEMICONDUCTOR DEVICE AND MANUFACTURING METHOD OF THE SAME

(71) Applicant: Nuvoton Technology Corporation, Hsinchu Science Park (TW)

(72) Inventors: In-Shiang CHIU, Taipei City (TW); Kuang-Chu CHEN, Hsinchu City (TW); Peng-Chan HSIAO, Taoyuan City (TW); Han-Ying LIU, Hsinchu City (TW)

(21) Appl. No.: 16/905,074

(22) Filed: Jun. 18, 2020

(30) Foreign Application Priority Data
Oct. 31, 2019 (TW) 108139420

(51) Int. Cl. H01L 27/16; H01L 35/34

(52) U.S. Cl. CPC H01L 27/16; H01L 35/08; H01L 35/34

(57) ABSTRACT

A semiconductor device is provided. The semiconductor device includes a substrate having a chamber. The semiconductor device also includes a first dielectric layer disposed on the substrate. The semiconductor device further includes a pair of thermocouples disposed on the first dielectric layer. The semiconductor device includes a second dielectric layer disposed on the first dielectric layer and between the thermocouples. The semiconductor device also includes an absorber connected to the thermocouples.

### CROSS REFERENCE TO RELATED APPLICATIONS

This application claims the benefit of Taiwan Application No. 108139420, filed Oct. 31, 2019, the entirety of which is incorporated by reference herein.

### BACKGROUND

### Technical Field

The embodiments of the present disclosure relate to a semiconductor device and a manufacturing method of the same, and in particular they relate to a semiconductor device that includes an isolation structure disposed between a pair of thermocouples and a manufacturing method of the same.

### Description of the Related Art

The thermoelectric effect is to directly convert the temperature difference into a voltage through thermocouples, and vice versa. This effect may be used to generate electrical energy, measure temperature, cool or heat objects.

In general, a thermal-sensing device is provided with thermocouples. After transmitting the heat of the object to be measured to the thermocouples, a voltage difference may be generated through the Seebeck effect, and then the temperature of the object to be measured may be measured via the voltage difference. Since the absolute value of the Seebeck coefficient of the semiconductor material must be greater than that of the metal material, the semiconductor material may be used to form a pair of thermocouples. However, the use of semiconductor material may create a depletion region at the junction of the pair of thermocouples. The depletion region may shorten the useful length of the thermocouples and affect the performance of the thermal-sensing device.

Therefore, existing semiconductor devices used to form thermal-sensing devices generally meet demands, but they are not satisfactory in all respects.

### BRIEF SUMMARY

The embodiments of the present disclosure relate to a semiconductor device that includes an isolation structure disposed between a pair of thermocouples and a manufacturing method of the same. In some embodiments, the thermocouples of the embodiments of the present disclosure are separated from each other by an isolation structure (a portion of the dielectric layer), which may prevent the generation of depletion regions, and thus may improve the useful length of the thermocouples and improve the sensing performance of the semiconductor device.

In accordance with some embodiments of the present disclosure, a semiconductor device is provided. The semiconductor device includes a substrate having a chamber. The semiconductor device also includes a first dielectric layer disposed on the substrate. The semiconductor device further includes a pair of thermocouples disposed on the first dielectric layer. The semiconductor device includes an isolation structure disposed between the thermocouples. The semiconductor device also includes an absorber connected to the thermocouples.

In accordance with some embodiments of the present disclosure, a semiconductor device is provided. The semiconductor device includes a substrate having a chamber. The semiconductor device also includes a first dielectric layer disposed on the substrate. The semiconductor device further includes a pair of thermocouples disposed on the first dielectric layer. The semiconductor device includes a second dielectric layer disposed on the first dielectric layer and between the thermocouples. The semiconductor device also includes an absorber connected to the thermocouples.

In accordance with some embodiments of the present disclosure, a manufacturing method of a semiconductor device is provided. The manufacturing method of the semiconductor device includes providing a substrate. The manufacturing method of the semiconductor device also includes forming a recess in the substrate. The manufacturing method of the semiconductor device further includes forming a filling structure to fill the recess. The manufacturing method of the semiconductor device includes forming a first dielectric on the filling structure. The manufacturing method of the semiconductor device also includes forming a conductive structure on the first dielectric layer. The manufacturing method of the semiconductor device further includes patterning the conductive structure to form a pair of thermocouples. The manufacturing method of the semiconductor device includes forming a second dielectric layer on the first dielectric layer and between the thermocouples. The manufacturing method of the semiconductor device also includes forming an absorber to connect to the pair of thermocouples. The manufacturing method of the semiconductor device further includes removing the filling structure to form a chamber.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIG. 1 is a partial schematic diagram illustrating one stage of forming the semiconductor device shown in FIG. 7 according to some embodiments of the present disclosure.

FIG. 2 is a partial schematic diagram illustrating one stage of forming the semiconductor device shown in FIG. 7 according to some embodiments of the present disclosure.

FIG. 3 is a partial schematic diagram illustrating one stage of forming the semiconductor device shown in FIG. 7 according to some embodiments of the present disclosure.

FIG. 4 is a partial schematic diagram illustrating one stage of forming the semiconductor device shown in FIG. 7 according to some embodiments of the present disclosure.

FIG. 5 is a partial schematic diagram illustrating one stage of forming the semiconductor device shown in FIG. 7 according to some embodiments of the present disclosure.

FIG. 6 is a partial schematic diagram illustrating one stage of forming the semiconductor device shown in FIG. 7 according to some embodiments of the present disclosure.

FIG. 7 is a partial schematic diagram illustrating the semiconductor device according to some embodiments of the present disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the relevant art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

In the embodiments of the present disclosure, a portion of the dielectric layer in the semiconductor device may be used as an isolation structure between a pair of thermocouples. The isolation structure may prevent the thermocouples from overlapping to form depletion region and maximize the useful length of the thermocouples and reduce the noise equivalent temperature difference (NETD), thereby improving the performance (e.g., sensing performance) of the semiconductor device.

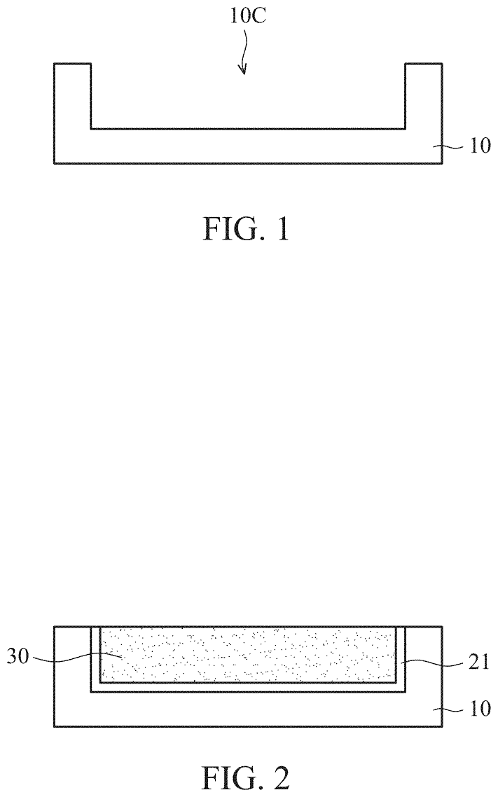

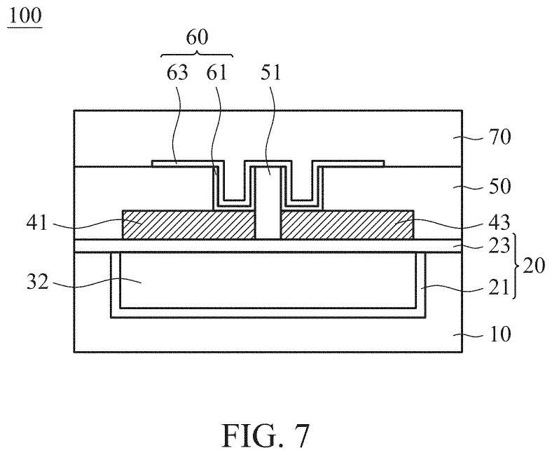

FIG. 1 to FIG. 7 are partial schematic diagrams illustrating various stages of forming the semiconductor device 100 shown in FIG. 7 according to some embodiments of the present disclosure. It should be noted that in order to show the features of the embodiments of the present disclosure, FIG. 1 to FIG. 7 illustrate the semiconductor device 100 in a cross-sectional manner, but they do not represent specific cross-sections of the semiconductor device 100. Moreover, some components may be omitted in FIG. 1 to FIG. 7.

Referring to FIG. 1, a substrate 10 is provided. In some embodiments, the substrate 10 may include an elementary semiconductor (e.g., silicon or germanium), a compound semiconductor (e.g., silicon carbide (SiC), gallium nitride (GaN), gallium arsenic (GaAs), gallium phosphide (GaP), indium phosphide (InP), indium arsenide (InAs), indium antimonide (InSb), and so on), an alloy semiconductor (e.g., silicon germanium, gallium arsenic phosphide, aluminum indium phosphide, aluminum gallium arsenide, gallium indium arsenide, gallium indium phosphide, gallium indium arsenide phosphide, and so on), any other applicable semiconductor, or a combination thereof, but the present disclosure is not limited thereto.

In some embodiments, the substrate 10 may be a semiconductor-on-insulator (SOI) substrate. The semiconductor-on-insulator substrate may include a bottom substrate, a buried oxide layer disposed on the bottom substrate, and a semiconductor layer disposed on the buried oxide layer. In some embodiments, the substrate 10 may be a semiconductor wafer (e.g., a silicon wafer, or any other applicable semiconductor wafer).

In some embodiments, the substrate 10 may include various isolation features to separate various device regions in the substrate 10. For example, the isolation features may include a shallow trench isolation (STI) feature, but the present disclosure is not limited thereto. The formation of a shallow trench isolation feature may include etching a trench in the substrate 10 and filling in the trench with insulating materials (e.g., silicon oxide, silicon nitride, or silicon oxynitride). The filled trench may have a multi-layer structure (e.g., a thermal oxide liner layer and silicon nitride filling the trench). A chemical mechanical polishing (CMP) process may be performed to polish back excessive insulating materials and planarize the top surface of the isolation features.

Then, referring to FIG. 1, a recess 10C is formed in the substrate 10. In some embodiments, a patterned photoresist layer (not shown) may be formed on the substrate 10. For example, the patterned photoresist layer may be a positive photoresist or a negative photoresist. In some embodiments, the patterned photoresist layer may be a single-layer or multi-layer structure, and the patterned photoresist layer may be formed through, for example, a deposition process, a photolithography process, any other applicable process, or a combination thereof, but the present disclosure is not limited thereto.

In some embodiments, an etching process may be performed and the substrate 10 may be etched through the patterned photoresist layer to form the recess 10C. In some embodiments, the etching process may include dry etching, wet etching, reactive ion etching (RIE), and/or any other applicable process. For example, the dry etching process may use argon (Ar), fluorine-containing gas (e.g., CF₄, SF₆, CH₂F₂, CHF₃, C₂F₆ and/or BF₃), chlorine-containing gas (e.g., Cl₂, CHCl₃, CCl₄ and/or BCl₃), bromine-containing gas (e.g., HBr, CHBr₃), any other applicable gas and/or plasma, and/or a combination thereof. For example, the wet etching process may include etching in the following solution: diluted hydrofluoric acid (DHF), a solution including hydrofluoric acid (HF), nitric acid (HNO₃), and/or acetic acid (CH₃COOH), or any other applicable wet etchant. However, the present disclosure is not limited thereto.

Referring to FIG. 2, a filling structure 30 is formed to fill the recess 10C. In some embodiments, the filling structure 30 may be formed of polysilicon, but the present disclosure is not limited thereto. In some embodiments, the filling structure 30 may be formed by a chemical vapor deposition (CVD), a physical vapor deposition (PVD) (e.g., vacuum evaporation process or sputtering process), any other applicable process, or a combination thereof, but the present disclosure is not limited thereto.

In some embodiments, a dielectric layer 21 may be formed in the recess 10C before forming the filling structure 30 to fill the recess 10C. More specifically, the dielectric layer 21 is formed on the sidewalls and bottom of the recess 10C (and the top surface of the substrate 10 in some embodiments). In some embodiments, the material of the dielectric layer 21 may include silicon oxide, silicon nitride, silicon oxynitride, high-κ dielectric material, any other applicable dielectric material, or a combination thereof, but the present disclosure is not limited thereto. In some embodiments, the high-κ dielectric material may include LaO, AlO, ZrO, TiO, Ta₂O₅, Y₂O₃, SrTiO₃ (STO), BaTiO₃ (BTO), BaZrO, HfO₂, HfO₃, HfZrO, HfLaO, HfSiO, HfSiON, LaSiO, AlSiO, HfTaO, HfSiO, HfTaTiO, HfAlON, (Ba,Sr)TiO₃ (BST), Al₂O₃, any other applicable high-κ dielectric material, or a combination thereof.

In some embodiments, the dielectric layer 21 may be formed by a deposition process. For example, the dielectric layer 21 may be formed by a chemical vapor deposition (CVD), an atomic layer deposition (ALD), or a spin coating, but the present disclosure is not limited thereto. In some embodiments, the chemical vapor deposition may be a low pressure chemical vapor deposition (LPCVD), a low temperature chemical vapor deposition (LTCVD), or a plasma enhanced chemical vapor deposition (PECVD).

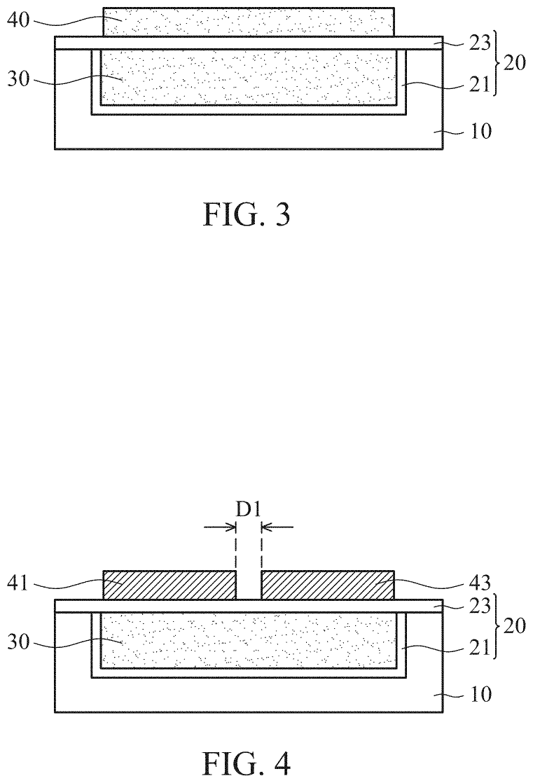

Referring to FIG. 3, a dielectric layer 23 is formed on the filling structure 30. In more detail, the dielectric layer 23 is formed on the filling structure 30 and part of the substrate 10. In some embodiments, the dielectric layer 21 and the dielectric layer 23 may be referred to as the first dielectric layer 20. That is, one portion of the first dielectric layer 20 may be formed on the sidewalls and bottom of the recess 10C, and another portion of the first dielectric layer 20 may be formed on part of the substrate 10. In some embodiments, the dielectric layer 23 may be formed by a thermal oxidation, but the present disclosure is not limited thereto. In some embodiments, the material of the dielectric layer 23 may be the same as or similar to the material of the dielectric layer 21, and the dielectric layer 23 may be formed by a deposition process. For example, the dielectric layer 23 may be formed by a chemical vapor deposition (CVD), an atomic layer deposition (ALD), or a spin coating, but the present disclosure is not limited thereto. Examples of chemical vapor deposition may be as described above, and will not be repeated here, but the present disclosure is not limited thereto.

Then, referring to FIG. 3, a conductive structure 40 is formed on the first dielectric layer 20. In more detail, the conductive structure 40 is formed on the dielectric layer 23. In some embodiments, the conductive structure 40 may include a semiconductor material, such as polysilicon, but the present disclosure is not limited thereto. In some embodiments, the conductive structure 40 may be formed by a chemical vapor deposition (CVD), a physical vapor deposition (PVD) (e.g., vacuum evaporation process or sputtering process), any other applicable process, or a combination thereof, but the present disclosure is not limited thereto.

Referring to FIG. 4, the conductive structure 40 is patterned to form a pair of thermocouples. In more detail, an ion implantation is performed after patterning the conductive structure 40 to form thermocouples 41, 43. In some embodiments, the conductive structure 40 may be first patterned by a lithography and etching process to form two separate components as shown in FIG. 4; then, the two separate components are separately subjected to different ion implantations to form thermocouples 41, 43.

For example, the thermocouples 41, 43 may be formed by ion implantations and a thermal process (e.g., annealing process), but the present disclosure is not limited thereto. In some embodiments, the material of the thermocouple 41 is, for example, silicon, and the thermocouple 41 may include dopants such as nitrogen, phosphorus, arsenic, antimony, and bismuth. That is, the material of the thermocouple 41 may include an N-type semiconductor. In some embodiments, the material of the thermocouple 43 is, for example, silicon, and the thermocouple 43 may include dopants such as boron, aluminum, gallium, indium, and thallium. That is, the material of the thermocouple 43 may include a P-type semiconductor (e.g., P-type heavily doped polysilicon), but the present disclosure is not limited thereto. In some other embodiments, the material of the thermocouple 41 may include a P-type semiconductor (e.g., P-type heavily doped polysilicon), and the material of the thermocouple 41 may include an N-type semiconductor.

In some embodiments, the conductive structure 40 is patterned by a lithography and etching process before the thermocouples 41 and 43 are formed, so that the thermocouples 41 and 43 are separated from each other by a distance D1. In some embodiments, the distance D1 may be at least greater than 0.1 μm.

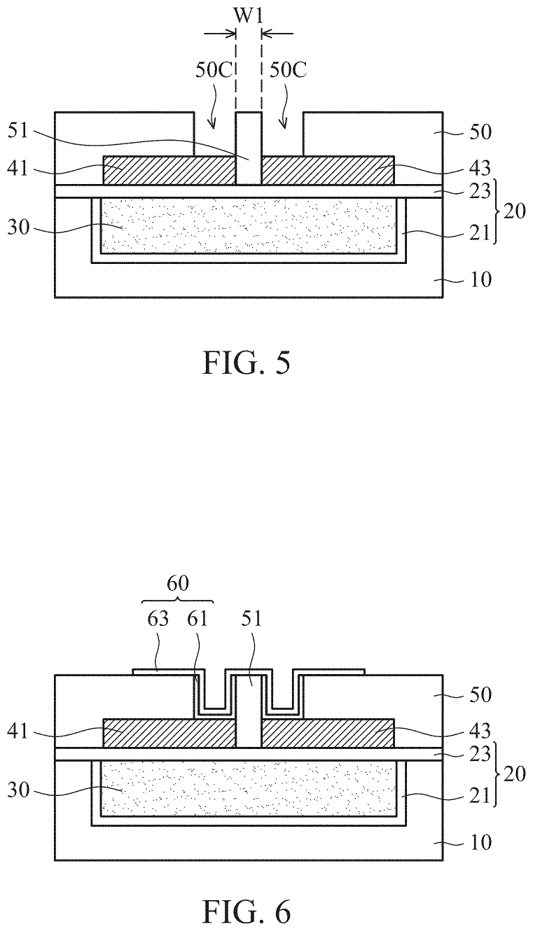

Referring to FIG. 5, a second dielectric layer 50 is formed on the first dielectric layer 20. In some embodiments, the second dielectric layer 50 may be the same as or similar to the first dielectric layer 20. For example, the material of the second dielectric layer 50 may include silicon oxide, silicon nitride, silicon oxynitride, high-κ dielectric material, any other applicable dielectric material, or a combination thereof, but the present disclosure is not limited thereto. In some embodiments, the high-κ dielectric material may include LaO, AlO, ZrO, TiO, Ta₂O₅, Y₂O₃, SrTiO₃ (STO), BaTiO₃ (BTO), BaZrO, HfO₂, HfO₃, HfZrO, HfLaO, HfSiO, HfSiON, LaSiO, AlSiO, HfTaO, HfSiO, HfTaTiO, HfAlON, (Ba,Sr)TiO₃ (BST), Al₂O₃, any other applicable high-κ dielectric material, or a combination thereof.

In some embodiments, the second dielectric layer 50 may be formed by a deposition process. For example, the second dielectric layer 50 may be formed by a chemical vapor deposition (CVD), an atomic layer deposition (ALD), or a spin coating, but the present disclosure is not limited thereto. Examples of chemical vapor deposition may be as described above, and will not be repeated here.

In some embodiments, the second dielectric layer 50 is a patterned dielectric layer. For example, a dielectric material may be formed on the thermocouples 41, 43, formed between the thermocouples 41, 43, and formed on the first dielectric layer 20. Next, the dielectric material is patterned to form at least two recesses 50C, and the two recesses 50C respectively expose portions of the top surfaces of the thermocouples 41 and 43. The patterning process includes, for example, photolithography and etching processes, which will not be repeated here.

As shown in FIG. 5, the portion of the second dielectric layer 50 between the thermocouples 41 and 43 may be regarded as an isolation structure 51. That is, the isolation structure 51 may be disposed between the thermocouples 41 and 43 to separate the thermocouples 41 and 43 from each other. In some embodiments, the width W1 of the isolation structure may be equal to or close to the distance D1, but the present disclosure is not limited thereto.

Since a portion of the second dielectric layer 50 may be used as an isolation structure 51 between the thermocouples 41 and 43, it may prevent the thermocouples 41, 43 from overlapping each other to form a depletion region. In addition, by providing the isolation structure 51, the useful length of the thermocouples 41, 43 may be improved (e.g., increased), and the noise equivalent temperature difference (NETD) may be reduced, thereby improving the performance (e.g., sensing performance) of the semiconductor device 100.

Referring to FIG. 6, an absorber 60 is formed to connect to the pair of thermocouples 41, 43. The absorber 60 may be used to receive thermal energy and transfer the thermal energy to the thermocouples 41, 43. In some embodiments, the absorber 60 may include a connecting layer 61 and a heat-absorbing layer 63. The material of the connecting layer 61 may include titanium (Ti), and the material of the heat-absorbing layer 63 may include titanium nitride (TiN), but the present disclosure is not limited thereto.

In some embodiments, a portion of the absorber 60 may be disposed in the two recesses 50C. Specifically, the connecting layer 61 may be disposed in the two recesses 50C. For example, the connecting layer 61 may be disposed on the bottom surfaces of the two recesses 50C (and thus be in direct contact with the exposed top surfaces of the thermocouples 41, 43), but the present disclosures is not limited thereto. The heat-absorbing layer 63 may be disposed on the connecting layer 61 and the second dielectric layer 50. For example, the heat-absorbing layer 63 may be disposed on the connecting layer 61 in the two recesses 50C, and may be disposed on the isolation structure 51 and a portion of the second dielectric layer 50, but the present disclosures is not limited thereto. In some embodiments, the connecting layer 61 and the heat-absorbing layer 63 may be formed by a chemical vapor deposition (CVD), a physical vapor deposition (PVD) (e.g., vacuum evaporation process or sputtering process), any other applicable process, or a combination thereof, but the present disclosure is not limited thereto.

Referring to FIG. 7, a third dielectric layer 70 is formed on the second dielectric layer 50. As shown in FIG. 7, the third dielectric layer 70 may fill the two recesses 50C of the second dielectric layer 50. Similarly, the material of the third dielectric layer 70 may be the same as or similar to the material of the first dielectric layer 20 or the material of the second dielectric layer 50. For example, the material of the third dielectric layer 70 may include silicon oxide, silicon nitride, silicon oxynitride, high-κ dielectric material, any other applicable dielectric material, or a combination thereof, but the present disclosure is not limited thereto. Examples of high-κ dielectric material may be as described above, and will not be repeated here. In some embodiments, the third dielectric layer 70 may be formed by a deposition process. For example, the third dielectric layer 70 may be formed by a chemical vapor deposition (CVD), an atomic layer deposition (ALD), or a spin coating, but the present disclosure is not limited thereto. Examples of chemical vapor deposition may be as described above, and will not be repeated here.

Then, referring to FIG. 7, the filling structure 30 is removed to form a chamber 32. For example, an etching process may be performed, and the third dielectric layer 70, the second dielectric layer 50, the thermocouples 41, 43, and the first dielectric layer 20 are etched through a specific patterned photoresist to form an etching trench (not shown). Examples of the etching process may be as described above, which will not be repeated here, but the present disclosure is not limited thereto.

Then, the filling structure 30 is removed through the etching trench to form the chamber 32 in the area occupied by the original filling structure 30 to form the semiconductor device 100. For example, the filling structure 30 may be plasma etched by passing gas through the etching trench to form the chamber 32, thereby forming the thermocouples 41, 43 into a suspended structure, but the present disclosure is not limited thereto.

As shown in FIG. 7, in some embodiments, the semiconductor device 100 includes a substrate 10 having a chamber 32. In some embodiments, the semiconductor device 100 also includes a first dielectric layer 20 disposed on the chamber 32 (and a portion of the first dielectric layer 20 surrounds the chamber 32). In more detail, the first dielectric layer 20 includes the dielectric layer 21 and the dielectric layer 23, the dielectric layer 21 is disposed on the sidewalls and the bottom of the chamber 32, and the dielectric layer 23 is disposed on the top of the chamber 32. In some embodiments, the semiconductor device 100 further includes a pair of thermocouples 41, 43 disposed on the first dielectric layer 20 (the dielectric layer 23). In some embodiments, the semiconductor device 100 includes an isolation structure 51 disposed between the thermocouples 41 and 43. In some embodiments, the semiconductor device 100 also includes an absorber 60 connected to the thermocouples 41, 43.

In some embodiments, the semiconductor device 100 may be used as a thermal-sensing device. The sensitivity of the thermal-sensing device may be determined by the Seebeck effect (thermoelectric effect). In the Seebeck effect, the voltage V measured by the thermal-sensing device may be calculated using the following formula: V=(αA−αB)×ΔT, wherein αA and αB are the Seebeck coefficients of the thermocouples 41 and 43, respectively, and ΔT is the temperature difference between the positions where the thermocouples 41, 43 are connected and their two sides.

In some embodiments, the materials used in the thermocouples 41, 43 of the semiconductor device 100 may be a P-type semiconductor (e.g., P-type silicon) and an N-type semiconductor (e.g., N-type silicon), so that the difference of the Seebeck coefficients of the thermocouples 41 and 43 is larger. Therefore, even if the temperature difference ΔT is small, a larger voltage V may be obtained. That is, the sensitivity of the semiconductor device 100 may be further improved.

Moreover, since a portion of the second dielectric layer 50 may be used as an isolation structure 51 between the thermocouples 41 and 43, it may prevent the thermocouples 41, 43 from overlapping each other to form a depletion region. In addition, by providing the isolation structure 51, the useful length of the thermocouples 41, 43 may be improved (e.g., increased), and the noise equivalent temperature difference (NETD) may be reduced, thereby improving the performance (e.g., sensing performance) of the semiconductor device 100.

In the embodiments of the present disclosure, as the sensitivity of the semiconductor device 100 is improved, it may be applied to more precise sensing devices. For example, the semiconductor device 100 according to the embodiments of the present disclosure may be applied to self-driving cars, (infrared) cameras, household electronic devices, etc. However, the present disclosure is not limited thereto.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. A semiconductor device, comprising:
a substrate having a chamber;
a first dielectric layer disposed on the substrate;
a pair of thermocouples disposed on the first dielectric layer;
an isolation structure disposed between the thermocouples; and
an absorber connected to the thermocouples.

2. The semiconductor device as claimed in claim 1, wherein a material of the thermocouples comprises an N-type semiconductor and a P-type semiconductor.

3. The semiconductor device as claimed in claim 2, further comprising:
a second dielectric layer disposed on the first dielectric layer and the thermocouples,
wherein the second dielectric layer has at least two recesses, and a portion of the absorber is disposed in the recesses.

4. The semiconductor device as claimed in claim 3, further comprising:
a third dielectric layer disposed on the second dielectric layer.

5. The semiconductor device as claimed in claim 4, wherein the third dielectric layer fills the recesses.

6. The semiconductor device as claimed in claim 3, wherein the absorber comprises:
a connecting layer disposed in the recesses; and
a heat-absorbing layer disposed on the connecting layer and the second dielectric layer.

7. The semiconductor device as claimed in claim 6, wherein a material of the connecting layer comprises titanium nitride, and a material of the heat-absorbing layer comprises titanium nitride.

8. A semiconductor device, comprising:
a substrate having a chamber;
a first dielectric layer disposed on the substrate;
a pair of thermocouples disposed on the first dielectric layer;
a second dielectric layer disposed on the first dielectric layer and between the thermocouples; and
an absorber connected to the thermocouples.

9. The semiconductor device as claimed in claim 8, wherein a portion of the second dielectric layer disposed between the thermocouples is used as an isolation structure.

10. The semiconductor device as claimed in claim 9, wherein the material of the thermocouples comprises an N-type semiconductor and a P-type semiconductor.

11. The semiconductor device as claimed in claim 9, wherein the second dielectric layer has at least two recesses, the recesses are respectively disposed on two sides of the isolation structure, and a portion of the absorber is disposed in the recesses.

12. The semiconductor device as claimed in claim 11, further comprising:
a third dielectric layer disposed on the second dielectric layer.

13. The semiconductor device as claimed in claim 12, wherein the third dielectric layer fills the recesses.

14. The semiconductor device as claimed in claim 11, wherein the absorber comprises:
a connecting layer disposed in the recesses; and
a heat-absorbing layer disposed on the connecting layer and the second dielectric layer.

15. A manufacturing method of a semiconductor device, comprising:
providing a substrate;
forming a recess in the substrate;
forming a filling structure to fill the recess;
forming a first dielectric on the filling structure;
forming a conductive structure on the first dielectric layer;
patterning the conductive structure to form a pair of thermocouples;
forming a second dielectric layer on the first dielectric layer and between the thermocouples;
forming an absorber to connect to the pair of thermocouples; and
removing the filling structure to form a chamber.

16. The manufacturing method of the semiconductor device as claimed in claim 15, further comprising:
performing ion implantation after patterning the conductive structure to form the pair of thermocouples.

17. The manufacturing method of the semiconductor device as claimed in claim 15,
patterning the second dielectric layer to form at least two recesses,
wherein the recesses expose a portion of top surfaces of the thermocouples.

18. The manufacturing method of the semiconductor device as claimed in claim 17, wherein a portion of the absorber is disposed in the recesses.

19. The manufacturing method of the semiconductor device as claimed in claim 15, further comprising:
forming a third dielectric layer on the second dielectric layer.
